(19) United States
(12) Patent Application Publication
(10) Pub. No.: US 2025/0218824 A1
(43) Pub. Date: Jul. 3, 2025

(54) HEAT TREATMENT APPARATUS

(71) Applicant: SCREEN Holdings Co., Ltd., Kyoto (JP)

(72) Inventors: Tomohiro UENO, Kyoto-shi, Kyoto (JP); Takahiro KITAZAWA, Kyoto-shi, Kyoto (JP)

(21) Appl. No.: 18/834,991

(22) PCT Filed: Oct. 4, 2022
(86) PCT No.: PCT/JP2022/037045

§ 371 Date: Jul. 31, 2024

(30) Foreign Application Priority Data
Mar. 23, 2022 (JP) 2022-047287

(51) Int. Cl. H01L 21/67; H05B 3/00

(52) U.S. Cl. CPC H01L 21/67248; H01L 21/67115; H05B 3/0047

(57) ABSTRACT

A heat treatment apparatus includes: a chamber housing a semiconductor wafer W; a halogen heating part and a flash heating part heating the semiconductor wafer; a plurality of sensors measuring a parameter relating to the heating of the semiconductor wafer; a storage part storing data measured by the plurality of sensors; and a calculation part predicting an output value of the first sensor in the plurality of sensors. The output value of the first sensor is predicted based on the data measured by the first sensor and the data measured by the second data in the plurality of sensors.

### TECHNICAL FIELD

The present invention relates to a heat treatment apparatus heating a thin plate-like precision electronic substrate (hereinafter referred to simply as a “substrate”) such as a semiconductor wafer.

### BACKGROUND ART

Processing of a semiconductor wafer is typically performed in a unit of lot (one group of semiconductor wafer subjected to the same processing under the same condition) in a heat treatment apparatus heating a substrate. A plurality of semiconductor wafers constituting a lot are transported into a chamber one by one and a heat treatment is performed in series in a sheetfed heat treatment apparatus.

When a heat treatment apparatus in a non-operation state starts a treatment of a lot of a semiconductor wafer or a treatment condition such as a treatment temperature of a semiconductor wafer is changed, a temperature of an in-chamber structure such as a susceptor holding the semiconductor wafer changes in some cases.

When the temperature of the in-chamber structure such as the susceptor changes in the process of treatment of the plurality of semiconductor wafers in the lot, there is a problem that a temperature history in the treatment differs between the semiconductor wafer early in the lot and the late semiconductor wafer. Accordingly, quality of each semiconductor wafer is also ununiform.

Japanese Patent Application Laid-Open No. 2020-043288 discloses an apparatus to solve such a problem. The apparatus described in Japanese Patent Application Laid-Open No. 2020-043288, a dummy wafer which is not to be processed is transported in a chamber and supported in a susceptor before a treatment of a lot is started, and heated in the same condition as a lot to be processed to previously make a temperature of an in-chamber structure such as a susceptor reach a stable temperature in processing.

### PRIOR ART DOCUMENTS

### Patent Document(s)

Patent Document 1: Japanese Patent Application Laid-Open No. 2020-043288

### SUMMARY

### Problem to be Solved by the Invention

In such a technique using the dummy wafer, a large number of dummy wafers need to be processed until the temperature of the in-chamber structure is stabilized, and such a configuration causes reduction of productivity. The temperature of the substrate needs to be grasped even in a state where the in-chamber structure does not reach the stable temperature to improve the productivity.

The present invention therefore has been made to solve the above problems, and it is an object to provide a heat treatment apparatus capable of measuring a temperature of a substrate in a chamber with high accuracy before reaching a stable temperature while suppressing reduction of productivity of the substrate.

### Means to Solve the Problem

In order to solve the above problem, the invention according to claim 1 includes: a chamber housing a substrate; a heating part heating the substrate; a plurality of sensors measuring a parameter relating to the heating of the substrate; a storage part storing data measured by the plurality of sensors; and a calculation part predicting an output value of the first sensor based on data measured by a first sensor and data measured by a second sensor having a correlation with the first sensor in the plurality of sensors.

The invention according to claim 2 is the heat treatment apparatus according to the invention of claim 1, wherein the calculation part predicts an output value of the first sensor based on one or more pieces of time-series data measured by the first sensor and one or more pieces of time-series data measured by the second sensor using a leaning model which has been previously created.

The invention according to claim 3 is the heat treatment apparatus according to claim 1 or 2, wherein the calculation part calculates a degree of accuracy between the output value which is predicted and data which is actually measured as a fitness value indicating a magnitude of correlation between the first sensor and the second sensor.

The invention according to claim 4 is the heat treatment apparatus according to any one of claims 1 to 3, wherein the plurality of sensors include a temperature sensor measuring a temperature of the substrate.

The invention according to claim 5 is the heat treatment apparatus according to any one of claims 1 to 4, wherein the plurality of sensors include a temperature sensor measuring a temperature of a wall surface of the chamber.

The invention according to claim 6 is the heat treatment apparatus according to any one of claims 1 to 5, further including: a preheating part irradiating the substrate housed in the chamber with light to preheat the substrate; and a main heating part irradiating the substrate with light to make the substrate reach a treatment temperature, wherein a light transmissive window transmitting light emitted from the preheating part and the main heating part is provided to the chamber, and the plurality of sensors include a temperature sensor measuring a temperature of the light transmissive window.

The invention according to claim 7 is the heat treatment apparatus according to the invention of claim 6, further including a susceptor locating the substrate and transmitting light emitted from the preheating part or the main heating part to the substrate, wherein the plurality of sensors include a temperature sensor measuring a temperature of the susceptor.

### Effects of the Invention

According to the invention of claim 1, 4, 5, 6, or 7, provided is the calculating predicting the output value of the first sensor based on the data measured by the first sensor and the data measured by the second sensor, thus the temperature of the substrate in the chamber can be measured with high accuracy before reaching the stable temperature while suppressing reduction of productivity of the substrate.

According to the invention of claim 2, the output value of the first sensor is predicted using the learning model which has been previously created based on one or more pieces of time-series data measured by the first sensor and one or more pieces of time-series data measured by the second sensor, thus the temperature of the substrate can be measured with higher accuracy.

According to the invention of claim 3, calculated is a degree of accuracy between the output value which is predicted and the data which is actually measured as the fitness value indicating the magnitude of correlation between the first sensor and the second sensor, thus the temperature of the substrate can be measured with higher accuracy.

### BRIEF DESCRIPTION OF DRAWINGS

FIG. 1 A cross-sectional view schematically illustrating a configuration of a heat treatment apparatus according to the present embodiment.

FIG. 2 A perspective view illustrating an entire external appearance of a holder.

FIG. 3 A plan view of a susceptor.

FIG. 4 A cross-sectional view of the susceptor.

FIG. 5 A plan view of a transfer mechanism.

FIG. 6 A side view of the transfer mechanism.

FIG. 7 A plan view illustrating an arrangement of a plurality of halogen lamps HL in a halogen heating part.

FIG. 8 A function block diagram schematically illustrating an electrical configuration of the heat treatment apparatus including a calculation part.

FIG. 9 A flow chart illustrating a processing procedure of creating a learning model.

FIG. 10 A diagram illustrating a relationship between an output value predicted in a first sensor, an actual measurement value of a second sensor, and a fitness value.

FIG. 11 A flow chart illustrating a processing procedure of a semiconductor wafer W using the learning model.

### DESCRIPTION OF EMBODIMENT(S)

Embodiments are described hereinafter with reference to the appended drawings. The embodiments also describe detailed features for description of a technique, for example, however, they are exemplification, and all of them are not necessary features to be able to implement the embodiments.

The drawings are schematically illustrated, thus a configuration is appropriately omitted or simplified for convenience of explanation. A mutual relationship of sizes and positions of configurations each illustrated in the different drawings is not necessarily illustrated accurately, but may be appropriately changed. A hatching may be assigned to easily understand contents of the embodiments also in the drawings which are not cross-sectional views but are plan views, for example.

In the description hereinafter, the same reference numerals will be assigned to the similar constituent elements in the drawings, and the constituent elements having the same reference numeral have the same name and function. Accordingly, the detailed description on them may be omitted to avoid a repetition in some cases.

An expression “comprising”, “including”, or “having” a certain constituent element is not an exclusive expression for excluding the presence of the other constituent elements unless otherwise described in the description hereinafter.

In the following description, even when ordinal numbers such as “first” or “second” are stated, the terms are used to facilitate understanding of contents of embodiments for convenience, and therefore, the usage of the ordinal numbers does not limit the indication of the ordinal numbers to ordering.

In the description hereinafter, unless otherwise noted, the expressions indicating relative or absolute positional relationships such as “in one direction”, “along one direction”, “parallel”, “orthogonal”, “central”, “concentric”, and “coaxial”, for example, include those exactly indicating the positional relationships and those where an angle or a distance is relatively changed within tolerance or to the extent that similar functions can be obtained.

In the description hereinafter, unless otherwise noted, the expressions indicating equality such as “same”, “equal”, “even”, or “uniform”, for example, include those indicating quantitatively exact equality and those in the presence of a difference within tolerance or to the extent that similar functions can be obtained.

In the following description, even when the terms indicating a specific position or direction such as “up”, “down”, “left”, “right”, “side”, “bottom”, “front”, “back”, for example, the terms are used to facilitate understanding of contents of embodiments for convenience, and therefore, they have no relationship to a position or a direction in an actual implement.

In the description hereinafter, “upper surface of ···” or “lower surface of . . . ” include a state where the other constituent element is formed on an upper surface or a lower surface of a target constituent element in addition to an upper surface itself or a lower surface itself of the target constituent element. That is to say, the description of “A provided to an upper surface of B”, for example, does not interrupt intervention of the other constituent element “C” between A and B.

### FIRST EMBODIMENT

A heat treatment apparatus relating to the present embodiment is described hereinafter.

### Configuration of Heat Treatment Apparatus 160

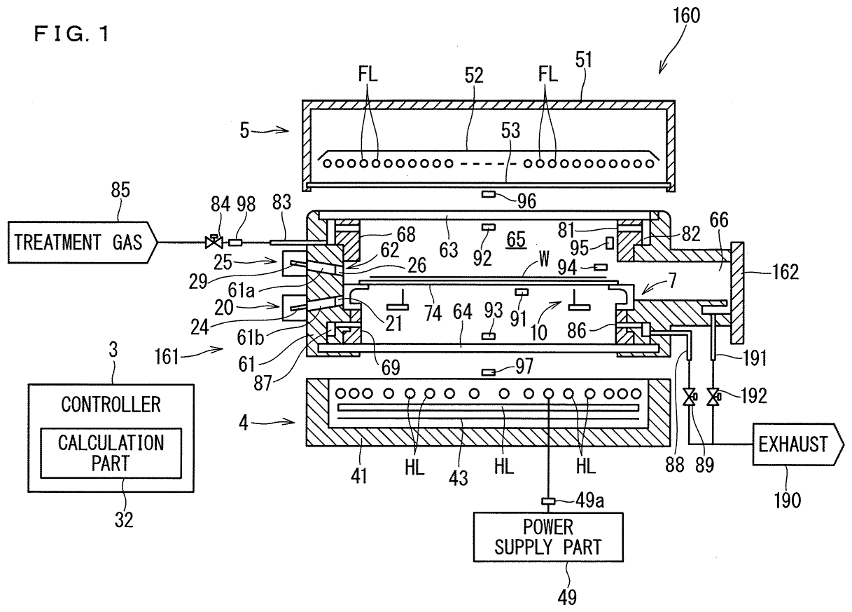

FIG. 1 is a cross-sectional view schematically illustrating a configuration of a heat treatment apparatus 160 according to the present embodiment.

As exemplified in FIG. 1, the heat treatment apparatus 160 according to the present embodiment is an apparatus performing light irradiation on a semiconductor wafer W having a disk-like shape as a substrate, thereby heating the semiconductor wafer W.

A size of the semiconductor wafer W to be processed is not particularly limited. For example, the semiconductor wafer W to be processed has a diameter of 300 mm or 450 mm (300 mm in the present embodiment).

The heat treatment apparatus 160 includes a chamber 161 for housing the semiconductor wafer W, a flash heating part 5 including a plurality of built-in flash lamps FL as a main heating part, and a halogen heating part 4 including a plurality of built-in halogen lamps HL as a preheating part. The flash heating part 5 is provided over the chamber 161, and the halogen heating part 4 is provided under the chamber 161. The heat treatment apparatus 160 further includes a controller 3 for controlling each operating mechanism provided to the halogen heating part 4, the flash heating part 5, and the chamber 161 to cause the operating mechanism to execute a heat treatment on the semiconductor wafer W. In the present embodiment, the controller 3 includes a calculation part 32 predicting an output value of a first sensor (any one S1 to S11) described hereinafter. The halogen heating part 4 includes the plurality of halogen lamps HL in the present embodiment, but may include arc lamps or light emitting diodes, that is LEDs in place of the halogen lamps HL. According to the above configuration, the semiconductor wafer W is heated while being housed in the chamber.

The plurality of flash lamps FL emit flash of light to heat the semiconductor wafer W. The plurality of halogen lamps HL continuously heat the semiconductor wafer W.

The heat treatment apparatus 160 includes a holder 7 provided inside the chamber 161 for holding the semiconductor wafer W in a horizontal posture, and a transfer mechanism 10 provided inside the chamber 161 for transferring the semiconductor wafer W between the holder 7 and the outside of the heat treatment apparatus 160.

An upper chamber window 63 made of quartz is mounted to an upper surface of a chamber chassis (chamber side portion 61) to block the chamber 161.

The upper chamber window 63 constituting a ceiling of the chamber 161 is a disk-shaped member made of quartz, and serves as a quartz window (light transmissive window) that transmits light emitted from the flash heating part 5 therethrough into the chamber 161.

The lower chamber window 64 constituting the floor of the chamber 161 is also a disk-shaped member made of quartz, and serves as a quartz window (light transmissive window) that transmits light emitted from the halogen heating part 4 therethrough into the chamber 161.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are formed into an annular shape.

The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, both the upper and lower reflective rings 68 and 69 are removably mounted to the chamber side portion 61.

An inner space of the chamber 161, that is to say, a space surrounded by the upper chamber window 63, the chamber chassis (chamber side portion 61), and the upper reflective ring 68 and is defined as a heat treatment space 65.

A recessed portion 62 is formed in an inner wall surface of the chamber 161 by mounting the upper and lower reflective rings 68 and 69 to the chamber side portion 61. That is to say, formed is the recessed portion 62 surrounded by a middle portion of the inner wall surface of the chamber side portion 61 where the reflective rings 68 and 69 are not mounted, a lower end surface of the upper reflective ring 68, and an upper end surface of the lower reflective ring 69.

The recessed portion 62 is formed into an annular shape along a horizontal direction in the inner wall surface of the chamber 161, and surrounds the holder 7 which holds the semiconductor wafer W. The chamber side portion 61 and the upper and lower reflective rings 68 and 69 are made of a metal material (e.g., stainless steel) with high strength and high heat resistance.

The chamber chassis (chamber side portion 61) is provided with a transport opening (throat) 66 for the transport of the semiconductor wafer W therethrough into and out of the chamber 161. The transport opening 66 can be opened and closed by the gate valve 162. The transport opening 66 is connected in communication with an outer peripheral surface of the recessed portion 62.

Thus, when the transport opening 66 is opened by the gate valve 162, the semiconductor wafer W can be transported through the transport opening 66 and the recessed portion 62 into and out of the heat treatment space 65. When the transport opening 66 is closed by the gate valve 162, the heat treatment space 65 in the chamber 161 is an enclosed space.

Upper and lower radiation thermometers 25 and 20 are attached to locations of an outer wall surface of the chamber side portion 61 where through holes 61a and 61b are provided, respectively. The through hole 61a is a cylindrical hole for directing infrared radiation emitted from an upper surface of the semiconductor wafer W held by a susceptor 74 to be described later therethrough to the upper radiation thermometer 25. The through hole 61b is a cylindrical hole for directing infrared radiation emitted from a lower surface of a semiconductor wafer W held by the susceptor 74 to be described later therethrough to the lower radiation thermometer 20. The through holes 61a and 61b are inclined with respect to a horizontal direction so that a longitudinal axis (an axis extending in a direction in which the through holes 61a and 61b extend through the chamber side portion 61) of the through holes 61a and 61b intersect a main surface of the semiconductor wafer W held by the susceptor 74. A transparent window 26 made of calcium fluoride material transmitting infrared radiation in a wavelength range measurable with the upper radiation thermometer 25 is mounted to an end portion of the through hole 61a which faces the heat treatment space 65. A transparent window 21 made of barium fluoride material transmitting infrared radiation in a wavelength range measurable with the lower radiation thermometer 20 is mounted to an end portion of the through hole 61b which faces the heat treatment space 65.

The upper radiation thermometer 25 is disposed obliquely above the semiconductor wafer W held by the susceptor 74, and receives the infrared radiation emitted from the upper surface of the semiconductor wafer W to measure the temperature of the upper surface. An infrared radiation sensor 29 of the upper radiation thermometer 25 includes an optical element of Indium antimony (InSb) to cope with a rapid temperature change in the upper surface of the semiconductor wafer W at the moment of a flash of light.

In the meanwhile, the lower radiation thermometer 20 is disposed obliquely below the semiconductor wafer W held by the susceptor 74, and receives the infrared radiation emitted from the lower surface of the semiconductor wafer W to measure the temperature of the lower surface. The lower radiation thermometer 20 is provided with an infrared radiation sensor 24 to measure the temperature of the lower surface of the semiconductor wafer W.

A parameter relating to heating of the semiconductor wafer W is measured by the upper radiation thermometer 25 and the lower radiation thermometer 20 described above. In addition, the heat treatment apparatus 160 includes a plurality of sensors measuring a parameter relating to heating of the semiconductor wafer W. For example, temperature sensors 91, 92, 93, 94, and 95 are disposed in the chamber 161. In each of the temperature sensors 91, 92, 93, 94, and 95, the temperature sensor 91 measures the susceptor 74, the temperature sensor 92 measures the upper chamber window 63, the temperature sensor 93 measures the lower chamber window 64, the temperature sensor 94 measures an atmosphere in the chamber, and the temperature sensor 95 measures the wall surface of the chamber 161.

At least one gas supply opening 81 for supplying a treatment gas therethrough into the heat treatment space 65 is provided to an upper portion of the inner wall of the chamber 161. The gas supply opening 81 is provided above the recessed portion 62, and may be provided to the upper reflective ring 68. The gas supply opening 81 is communicably connected to a gas supply pipe 83 through a buffer space 82 formed into an annular shape inside the side wall of the chamber 161.

The gas supply pipe 83 is connected to a treatment gas supply source 85. A valve 84 is inserted at some midpoint in the gas supply pipe 83. When the valve 84 is opened, the treatment gas is supplied from the treatment gas supply source 85 to the buffer space 82. A flowmeter 98 is connected on a downstream side of the valve 84, and a flow amount of the treatment gas passing through the valve 84 is measured by the flowmeter 98. This flowmeter 98 also serves as a sensor measuring a parameter relating to heating of the semiconductor wafer W.

The treatment gas which has flowed into the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen (N2) gas, and reactive gases such as hydrogen (H2) gas and ammonia (NH3) gas (although nitrogen gas is used in the present embodiment).

At least one gas exhaust opening 86 for exhausting a gas from the heat treatment space 65 is provided to a lower portion of the inner wall of the chamber 161. The gas exhaust opening 86 is provided below the recessed portion 62, and may be provided to the lower reflective ring 69. The gas exhaust opening 86 is communicably connected to a gas exhaust pipe 88 through a buffer space 87 formed into an annular shape inside the side wall of the chamber 161. The gas exhaust pipe 88 is connected to an exhaust mechanism 190. A valve 89 is inserted at some midpoint in the gas exhaust pipe 88. When the valve 89 is opened, the gas in the heat treatment space 65 is exhausted through the gas exhaust opening 86 and the buffer space 87 to the gas exhaust pipe 88.

The at least one gas supply opening 81 and the at least one gas exhaust opening 86 may include a plurality of gas supply openings 81 and a plurality of gas exhaust openings 86, respectively, arranged in a circumferential direction of the chamber 161, and may have a slit-like shape. The treatment gas supply source 85 and the exhaust mechanism 190 may be mechanisms provided to the heat treatment apparatus 160 or be utility systems in a factory in which the heat treatment apparatus 100 is installed.

A gas exhaust pipe 191 for exhausting the gas from the heat treatment space 65 is also connected to a distal end of the transport opening 66. The gas exhaust pipe 191 is connected through a valve 192 to the exhaust mechanism 190. By opening the valve 192, the gas in the chamber 161 is exhausted through the transport opening 66.

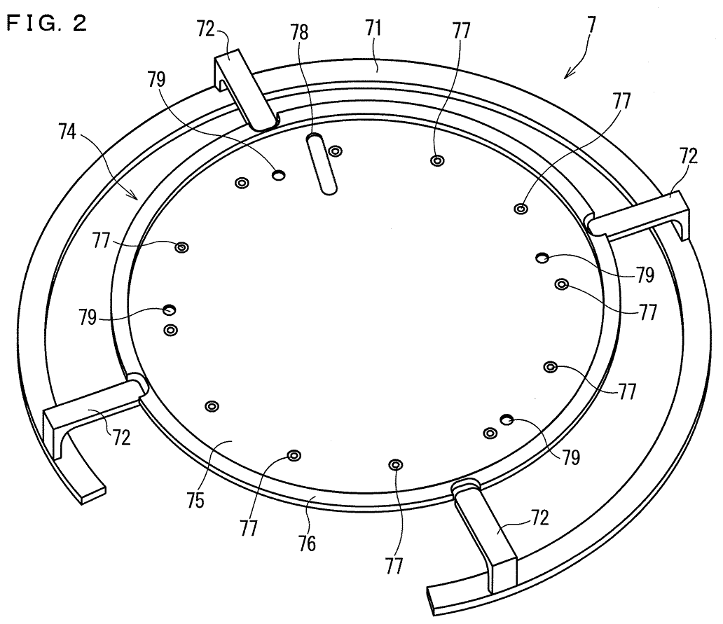

FIG. 2 is a perspective view illustrating an entire external appearance of the holder 7. The holder 7 includes a base ring 71, coupling portions 72, and the susceptor 74. The base ring 71, the coupling portions 72, and the susceptor 74 are all formed of quartz. In other words, the whole holder 7 is formed of quartz.

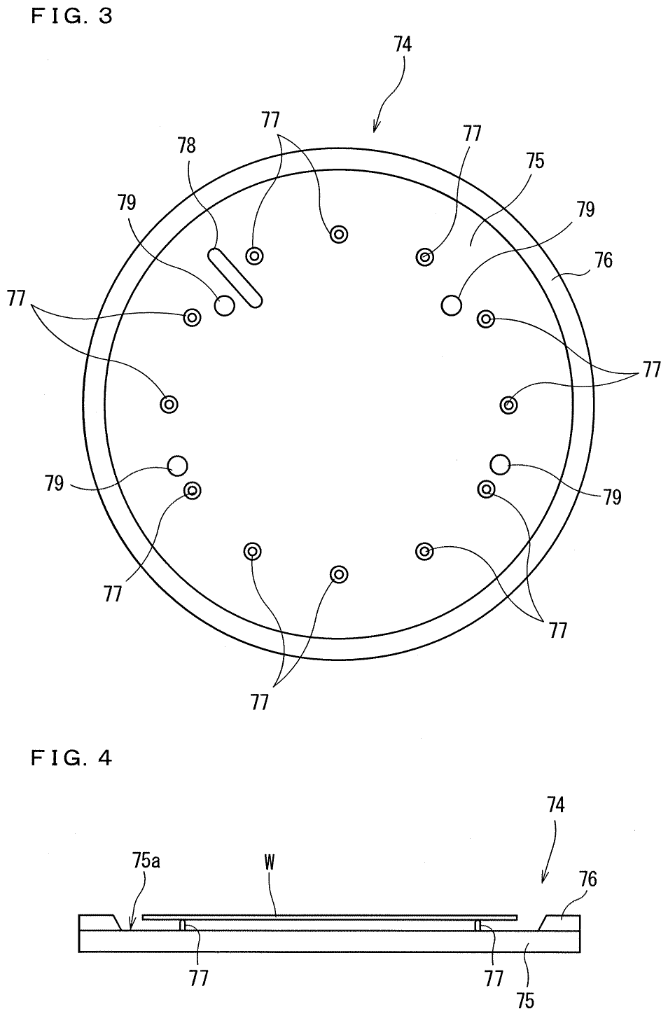

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by a wall surface of the chamber 161 by being placed on the bottom surface of the recessed portion 62 (with reference to FIG. 3). The plurality of coupling portions 72 (in the present embodiment, four coupling portions 72) are mounted upright on the upper surface of the base ring 71 along a circumferential direction of the annular shape thereof. The coupling portions 72 are also quartz members, and are rigidly secured to the base ring 71 by welding.

The susceptor 74 is supported by the four coupling portions 72 provided on the base ring 71 from a lower side. FIG. 3 is a plan view of the susceptor 74. FIG. 4 is a cross-sectional view of the susceptor 74.

The susceptor 74 includes a holding plate 75, a guide ring 76, and a plurality of support pins 77. The holding plate 75 is a substantially circular planar member formed of quartz. A diameter of the holding plate 75 is larger than that of the semiconductor wafer W. In other words, the holding plate 75 has a size, as seen in plan view, larger than that of the semiconductor wafer W.

The guide ring 76 is disposed on a peripheral part of the upper surface of the holding plate 75. The guide ring 76 is an annular member having an inner diameter larger than the diameter of the semiconductor wafer W. For example, when the diameter of the semiconductor wafer W is 300 mm, the inner diameter of the guide ring 76 is 320 mm.

The inner periphery of the guide ring 76 is in the form of a tapered surface which becomes wider in an upward direction from the holding plate 75. The guide ring 76 is formed of quartz similar to that of the holding plate 75.

The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The plurality of support pins 77 are provided to the holding surface 75a of the holding plate 75. In the present embodiment, a total of 12 support pins 77 are annularly provided upright at intervals of 30 degrees along the circumference of a circle concentric with the outer circumference of the holding surface 75a (the inner circumference of the guide ring 76).

The diameter of the circle on which the 12 support pins 77 are disposed (the distance between opposed ones of the support pins 77) is smaller than the diameter of the semiconductor wafer W, and is 210 to 280 mm when the diameter of the semiconductor wafer W is 300 mm. Three or more support pins 77 are provided. Each support pin 77 is formed of quartz.

The plurality of support pins 77 may be provided by welding on the upper surface of the holding plate 75 or machined integrally with the holding plate 75.

Referring again to FIG. 2, the four coupling portions 72 provided upright on the base ring 71 and the peripheral part of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 161, whereby the holder 7 is mounted to the chamber 161. With the holder 7 mounted to the chamber 161, the holding plate 75 of the susceptor 74 assumes a horizontal posture (a posture such that the normal to the holding plate 75 coincides with a vertical direction). In other words, the holding surface 75a of the holding plate 75 becomes a horizontal surface.

The semiconductor wafer W transported into the chamber 161 is placed and held in a horizontal posture on the upper side of the susceptor 74 of the holder 7 mounted to the chamber 161. At this time, the semiconductor wafer W is supported by the 12 support pins 77 provided upright on the holding plate 75, and is supported by the susceptor 74 from the lower side. More strictly speaking, the 12 support pins 77 have respective upper end portions coming in contact with the lower surface (back surface) of the semiconductor wafer W to support the semiconductor wafer W.

The semiconductor wafer W can be supported in a horizontal posture by the 12 support pins 77 because the 12 support pins 77 have a uniform height (distance from the upper ends of the support pins 77 to the holding surface 75a of the holding plate 75).

The semiconductor wafer W supported by the plurality of support pins 77 is spaced a predetermined distance apart from the holding surface 75a of the holding plate 75. A thickness of the guide ring 76 is larger than the height of the support pin 77. Thus, the guide ring 76 prevents the horizontal misregistration of the semiconductor wafer W supported by the plurality of support pins 77.

As illustrated in FIGS. 2 and 3, an opening 78 is formed in the holding plate 75 of the susceptor 74 so as to extend vertically through the holding plate 75 of the susceptor 74. The opening 78 is provided for the lower radiation thermometer 20 to receive radiation (infrared radiation) emitted from the lower surface of the semiconductor wafer W. That is to say, the lower radiation thermometer 20 receives the radiation emitted from the lower surface (back surface) of the semiconductor wafer W through the opening 78 and the transparent window 21 (mounted to the through hole 61b) in the chamber chassis (chamber side portion 61) to measure the temperature of the semiconductor wafer W.

The holding plate 75 of the susceptor 74 further includes four through holes 79 bored therein and designed so that lift pins 12 of the transfer mechanism 10 to be described later pass through the through holes 79, respectively, to transfer the semiconductor wafer W.

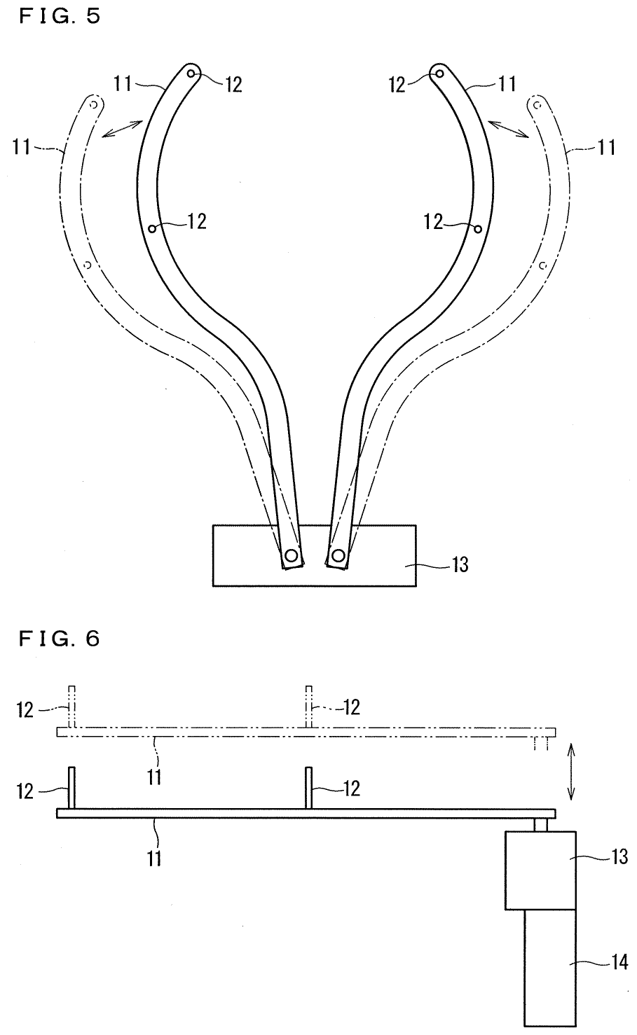

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62.

Each of the transfer arms 11 includes the two lift pins 12 mounted upright thereon. The transfer arms 11 and the lift pins 12 are formed of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which the semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in a plan view.

The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The pair of transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective through holes 79 (with reference to FIG. 2 and FIG. 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position.

The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 161.

Referring again to FIG. 1, the flash heating part 5 provided on an upper side of the chamber 161 includes a light source made up of the plurality of (in the present embodiment, 30) xenon flash lamps FL, and a reflector 52 provided to cover the upper side of the light source inside the chassis 51.

The flash heating part 5 further includes a lamp light radiation window 53 mounted to the bottom of the chassis 51. The lamp light radiation window 53 constituting the floor of the flash heating part 5 is a plate-like quartz window formed of quartz. The flash heating part 5 is provided over the chamber 161, whereby the lamp light radiation window 53 is opposed to the upper chamber window 63. The flash lamps FL direct a flash of light from over the chamber 161 through the lamp light radiation window 53 and the upper chamber window 63 toward the heat treatment space 65. A light volume sensor 96 is attached to the lamp radiation window 53, and the light volume sensor 96 detects a volume of light emitted from the flash lamps FL. This light volume sensor 96 may also serve as a sensor measuring a parameter relating to heating of the semiconductor wafer W.

The plurality of flash lamps FL, each of which is a rod-shaped lamp having an elongated cylindrical shape, are arranged in a plane so that the longitudinal directions of the respective flash lamps FL are in parallel with each other along a main surface (front surface) of the semiconductor wafer W held by the holder 7 (that is, along the horizontal direction). Thus, a plane defined by the arrangement of the flash lamps FL is also a horizontal plane.

Each of the flash lamps FL includes a rod-shaped glass tube (discharge tube) containing xenon gas sealed therein and having positive and negative electrodes provided on opposite ends thereof and connected to a capacitor, and a trigger electrode attached to an outer peripheral surface of the glass tube.

Because the xenon gas is electrically insulative, no current flows in the glass tube in a normal state even if electrical charge is stored in the capacitor. However, if high voltage is applied to the trigger electrode to produce an electrical breakdown, electricity stored in the capacitor flows momentarily in the glass tube, and xenon atoms or molecules are excited at this time to cause light emission.

Such a flash lamp FL has a property of being capable of emitting extremely intense light as compared with a light source that stays lit continuously such as a halogen lamp HL because electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp power source which supplies power to the flash lamps FL.

The reflector 52 is provided over the plurality of flash lamps FL so as to cover all of the flash lamps FL. A fundamental function of the reflector 52 is to reflect the flash of light emitted from the plurality of flash lamps FL toward the heat treatment space 65. The reflector 52 is a plate made of an aluminum alloy. An upper surface of the reflector 52 (a surface which faces the flash lamps FL) is roughened by a blasting treatment.

The halogen heating part 4 provided under the chamber 161 includes a chassis 41 incorporating the plurality of (in the present embodiment, 40) halogen lamps HL. The halogen heating part 4 directs light from under the chamber 161 through the lower chamber window 64 toward the heat treatment space 65 to heat the semiconductor wafer W by means of the plurality of halogen lamps HL. A light volume sensor 97 is attached to an upper side of the chassis 41, and the light volume sensor 97 detects a volume of light emitted from the flash lamps FL. This light volume sensor 97 may also serve as a sensor measuring a parameter relating to heating of the semiconductor wafer W.

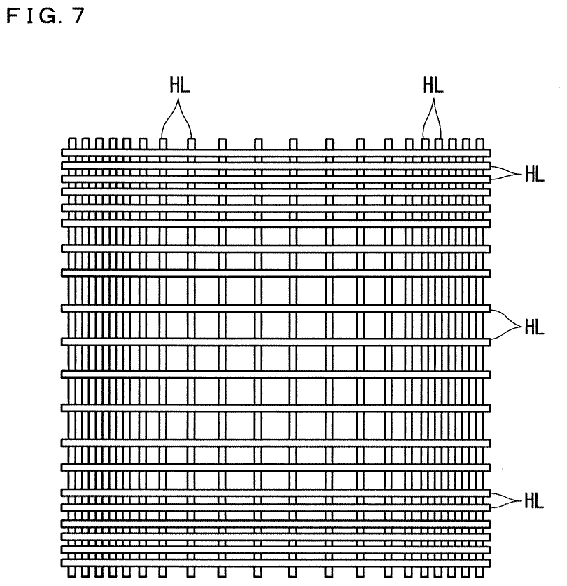

FIG. 7 is a plan view illustrating an arrangement of a plurality of halogen lamps HL in the halogen heating part 4. The 40 halogen lamps HL are arranged in two tiers, i.e. upper and lower tiers. 20 halogen lamps HL are arranged in the upper tier closer to the holder 7, and 20 halogen lamps HL are arranged in the lower tier farther from the holder 7 than the upper tier.

Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface (front surface) of the semiconductor wafer W held by the holder 7 (that is, in the horizontal direction). Thus, a plane defined by the arrangement of the halogen lamps

HL in each of the upper and lower tiers is also a horizontal plane.

As illustrated in FIG. 7, the halogen lamps HL in each of the upper and lower tiers are disposed at a higher density in a region opposed to a peripheral part of the semiconductor wafer W held by the holder 7 than in a region opposed to a central part thereof. In other words, the halogen lamps HL in each of the upper and lower tiers are arranged at shorter intervals in the peripheral part of the lamp arrangement than in the central part thereof. This allows a larger volume of light to impinge upon the peripheral part of the semiconductor wafer W where a temperature decrease is prone to occur when the semiconductor wafer W is heated by the irradiation thereof with light from the halogen heating part 4.

As illustrated in FIG. 1, voltage is applied to each of the plurality of halogen lamps HL from a power supply part 49, thus the halogen lamps HL emit light. The power supply part 49 individually adjusts power supplied to each of the plurality of halogen lamps HL under control of the controller 3. That is to say, the power supply part 49 can individually adjust emission intensity of each of the plurality of halogen lamps HL disposed in the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. Gas prepared by introducing a halogen element (iodine, bromine and the like) in trace amounts into inactive gas such as nitrogen, argon and the like is sealed in the glass tube. The introduction of the halogen element allows the temperature of the filament to be set at a high temperature while suppressing a break in the filament.

Thus, the halogen lamps HL have the properties of having a longer life than typical incandescent lamps and being capable of continuously emitting intense light. Thus, the halogen lamps HL are continuous lighting lamps that emit light continuously for at least not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL. A reflector 43 is provided also inside the chassis 41 of the halogen heating part 4 under the halogen lamps HL arranged in two tiers (FIG. 3). The reflector 43 reflects the light emitted from the plurality of halogen lamps HL toward the heat treatment space 65.

The heat treatment apparatus 160 further includes various cooling structures to prevent an excessive temperature rise in the halogen heating part 4, the flash heating part 5, and the chamber 161 because of the heat energy generated from the halogen lamps HL and the flash lamps FL during the heat treatment of the semiconductor wafer W. For example, a water cooling tube (not shown) is provided to the walls of the chamber 161. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

A treatment operation in the heat treatment apparatus 160 is described next. The processing procedure in the semiconductor wafer W described hereinafter proceeds when the controller 3 controls each operation mechanism of the heat treatment apparatus 160.

Firstly, the valve 84 for air supply is opened and the valve 89 for air exhaust are opened to start air supply and exhaust within the chamber 161 prior to the treatment of the semiconductor wafer W. When the valve 84 is opened, nitrogen gas is supplied from the gas supply opening 81 into the heat treatment space 65. Also, when the valve 89 is opened, the gas within the chamber 161 is exhausted through the gas exhaust opening 86. This causes the nitrogen gas supplied from an upper portion of the heat treatment space 65 in the chamber 161 to flow downwardly and then to be exhausted from a lower portion of the heat treatment space 65.

The gas within the chamber 161 is exhausted also through the transport opening 66 by opening the valve 192. Further, the exhaust mechanism not shown exhausts an atmosphere near the drivers of the transfer mechanism 10. The nitrogen gas is continuously supplied into the heat treatment space 65 at the time of the heat treatment of the semiconductor wafer W in the heat treatment apparatus 160, and an amount of supply is appropriately changed in accordance with a processing process.

Subsequently, the gate valve 162 is opened to open the transport opening 66. A transport robot outside the heat treatment apparatus 160 transports the semiconductor wafer W to be processed through the transport opening 66 into the heat treatment space 65 in the chamber 161. At this time, there is a possibility that the atmosphere outside the apparatus is carried into the heat treatment space 65 as the semiconductor wafer W is transported into the heat treatment space 65, however, the nitrogen gas is continuously supplied into chamber 161, thus the nitrogen gas flows through the transport opening 66 and it is possible to minimize an outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the support pins 77.

After the semiconductor wafer W is placed on the lift pins 12, the transport robot moves out of the heat treatment space 65, and the gate valve 162 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal posture from below. The semiconductor wafer W is supported by the plurality of support pins 77 provided upright on the holding plate 75, and is held by the susceptor 74. The semiconductor wafer W is held by the holder 7 in such a posture that a surface as a processed surface is the upper surface. A predetermined distance is defined between a back surface (a main surface opposite from the front surface) of the semiconductor wafer W supported by the plurality of support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held in the horizontal posture from below by the susceptor 74 of the holder 7 formed of quartz, the 40 halogen lamps HL in the halogen heating part 4 are turned on at the same time and preheating (or assist-heating) is started. Halogen light emitted from the halogen lamps HL is transmitted through the lower chamber window 64 and the susceptor 74 both formed of quartz, and impinges on the lower surface of the semiconductor wafer W. By receiving irradiation with light from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W which is on the increase by the irradiation with light from the halogen lamps HL is measured with the lower radiation thermometer 20. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature or not. In other words, the controller 3 effects feedback control of the output from the halogen lamps HL so that the temperature of the semiconductor wafer W is equal to the preheating temperature, based on the value measured with the lower radiation thermometer 20.

After the temperature of the semiconductor wafer W reaches the preheating

temperature, the controller 3 maintains the temperature of the semiconductor wafer W at the preheating temperature for a short time. Specifically, at a time when the temperature of the semiconductor wafer W measured with the lower radiation thermometer 20 reaches the preheating temperature, the controller 3 adjusts the output from the halogen lamps HL to maintain the temperature of the semiconductor wafer W at approximately the preheating temperature.

By performing such preheating using the halogen lamps HL, the temperature of the entire semiconductor wafer W is uniformly increased to the preheating temperature. In the stage of preheating using the halogen lamps HL, the semiconductor wafer W shows a tendency to be lower in temperature in the peripheral portion thereof where heat dissipation is liable to occur than in the central portion thereof. However, the halogen lamps HL in the halogen heating part 4 are disposed at a higher density in the region opposed to the peripheral portion of the semiconductor wafer W than in the region opposed to the central portion thereof. This causes a larger volume of light to impinge upon the peripheral portion of the semiconductor wafer W where heat dissipation is liable to occur, thereby providing a uniform in-plane temperature distribution of the semiconductor wafer W in the stage of preheating.

The flash lamps FL in the flash heating part 5 irradiate the front surface of the semiconductor wafer W held by the susceptor 74 with a flash of light at a time when a predetermined time period has elapsed since the temperature of the semiconductor wafer W reaches the preheating temperature. At this time, part of the flash of light emitted from the flash lamps FL travels directly toward the interior of the chamber 161. The remainder of the flash of light is reflected once from the reflector 52, and then travels toward the interior of the chamber 161. The irradiation of the semiconductor wafer W with such flashes of light achieves the flash heating of the semiconductor wafer W.

The flash heating, which is achieved by the emission of a flash of light from the flash lamps FL, is capable of increasing the temperature of the front surface of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The temperature of the front surface of the semiconductor wafer W flash-heated by the flash irradiation from the flash lamps FL is increased instantaneously to a treatment temperature of 1000° C. or more, and then the temperature of the front surface decreases rapidly.

When the flash heating treatment is finished, the halogen lamps HL are turned off after an elapse of a predetermined time. Accordingly, the temperature of the semiconductor wafer W decreases rapidly from the preheating temperature. The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement with the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 162, and the transport robot outside the heat treatment apparatus 160 transports the semiconductor wafer W placed on the lift pins 12 from the chamber 161. Thus, the heating treatment on the semiconductor wafer W is completed.

### <Calculation Part 32>

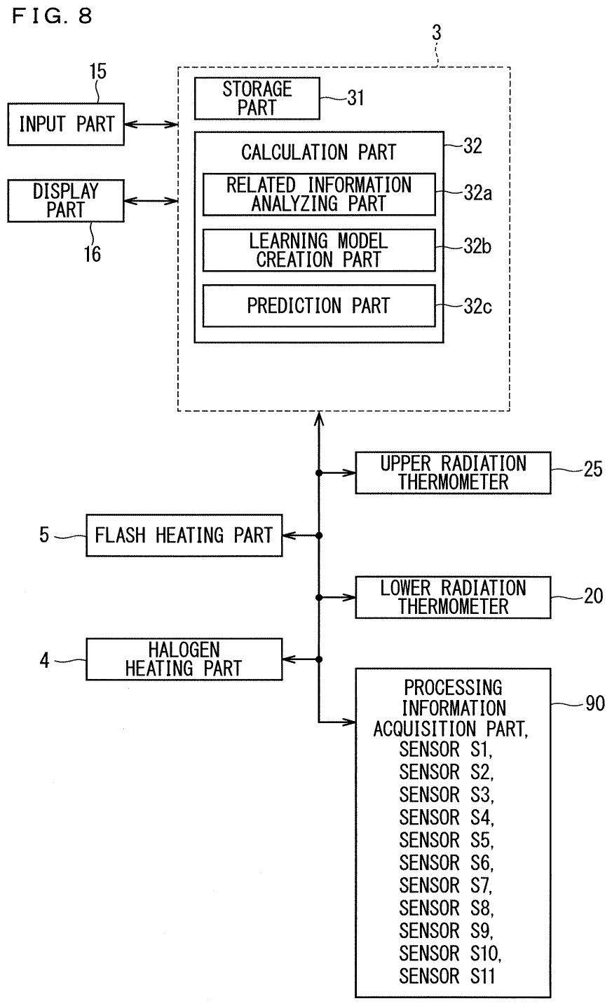

FIG. 8 is a function block diagram schematically illustrating an electrical configuration of the heat treatment apparatus 160 including the calculation part 32. The heat treatment apparatus 160 includes the controller 3, an input part 15, and a display part 16. The input part 15 includes an input apparatus such as a key board, a pointing device, and a touch panel. Furthermore, the input part 15 includes a communication module for communication with a host computer. The display part 16 includes a liquid crystal display, for example, and displays various types of information under control of the controller 3.

The controller 3 includes an arithmetic processing unit such as CPU. The controller 3 controls the flash heating part 5 and the halogen heating part 4, for example.

The controller 3 includes a storage part 31 and the calculation part 32. The storage part 31 includes a storage device such as a solid memory device and a hard disk drive. The storage part 31 stores data and a processing program. In the present embodiment, the storage part 31 stores data measured by a sensor (each of sensors S1 to S11 described hereinafter, for example) measuring a parameter relating to the heating of the semiconductor wafer W. The data includes recipe data. The recipe data is data of a plurality of recipes regulating processing contents and a processing procedure of the semiconductor wafer W.

The calculation part 43 includes a related information analyzing part 32a, a learning model creation part 32b, and a prediction part 32c described in detail hereinafter. The related information analyzing part 32a, the learning model creation part 32b, and the prediction part 32c are function processing part achieved by a CPU in the controller 3 executing a predetermined processing program. Processing details of the related information analyzing part 32a, the learning model creation part 32b, and the prediction part 32 will be described in more detail hereinafter.

As described above, the controller 3 executes a predetermined processing program, whereby the processes in the heat treatment apparatus 160 proceed. The controller 3 controls the halogen heating part 4 and the flash heating part 5 to perform the heat treatment on the semiconductor wafer W to increase the temperature of the semiconductor wafer W to a preset temperature, for example.

Returning to FIG. 1 again, the upper radiation thermometer 25 described above includes the infrared radiation sensor 29 measuring the temperature of the upper surface (front surface) of the semiconductor wafer W. The infrared radiation sensor 29 transmits a detection signal generated in response to light reception to the controller 3, and calculates the temperature of the upper surface of the semiconductor wafer W in the controller 3. In the similar manner, the lower radiation thermometer 20 includes the infrared radiation sensor 24 measuring the temperature of the lower surface (back surface) of the semiconductor wafer W. The infrared radiation sensor 24 transmits a detection signal generated in response to light reception to the controller 3, and calculates the temperature of the lower surface of the semiconductor wafer W in the controller 3. The upper radiation thermometer 25 and the lower radiation thermometer 20 calculate the temperature of the semiconductor wafer W in accordance with the transmissivity of an object to be measured from the detection signal generated in response to light reception. Accordingly, the transmissivity needs to be previously adjusted in accordance with the object to be measured. The adjustment of the transmissivity is described in detail hereinafter.

The controller 3 of the heat treatment apparatus 160 acquires the temperature of the semiconductor wafer W and plural pieces of data having correlation with the temperature of the semiconductor wafer W and stores them in the storage part 31. Examples of this data include a temperature of a quartz component in the chamber 161 (for example, a temperature of the susceptor 74, a temperature of the upper chamber window 63, and a temperature of the lower chamber window 64), a temperature of the wall surface of the chamber 161, a power amount supplied to the halogen heating part 4 (or each halogen lamp HL), a volume of light emitted from the halogen heating part 4 (or each halogen lamp HL), a supply amount of a treatment gas to the inner side of the chamber 161, and a volume of light emitted from the flash heating part 5 (or each flash lamp FL).

These pieces of data are acquired by each of the sensors S1 to S11 as a processing information acquisition part 90. For example, temperature data of the lower surface of the semiconductor wafer W is acquired by the lower radiation thermometer 20 (FIG. 1) (sensor S1 in FIG. 8), temperature data of the upper surface of the semiconductor wafer W is acquired by the upper radiation thermometer 25 (FIG. 1) (sensor S2 in FIG. 8), temperature data of the susceptor 74 is acquired by the temperature sensor 91 (FIG. 1) (sensor S3 in FIG. 8), temperature data of the upper chamber window 63 is acquired by the temperature sensor 92 (FIG. 1) (sensor S4 in FIG. 8), temperature data of the lower chamber window 64 is acquired by the temperature sensor 93 (FIG. 1) (sensor S5 in FIG. 8), temperature data of an atmosphere in the chamber 161 is acquired by the temperature sensor 94 (FIG. 1) (sensor S6 in FIG. 8), and temperature data of the wall surface of the chamber 161 is acquired by the temperature sensor 95 (FIG. 1) (sensor S7 in FIG. 8). A power amount supplied to the halogen heating part 4 (or each halogen lamp HL) is acquired by an ammeter 49a (FIG. 1) (sensor S8 in FIG. 8) connected to the power supply part 49, a volume of light emitted from the halogen heating part 4 (or each halogen lamp HL) is acquired by the light volume sensor 97 (FIG. 1) (sensor S9 in FIG. 8), a supply amount of the treatment gas to the inner side of the chamber 161 is acquired by the flowmeter 98 (FIG. 1) (sensor S10 in FIG. 8) connected to the gas supply pipe 83, and a volume of light emitted from the flash heating part 5 (sensor S11 in FIG. 8) is acquired by the light volume sensor 96 (FIG. 1) (sensor S11 in FIG. 8). These pieces of data can be used for creating the learning model. Data having correlation with the temperature data of the semiconductor wafer W, for example, is selected for creating the learning model in the data acquired by each of the sensors S1 to S11 as the processing information acquisition part 90. As the sensor acquiring this data, it is preferable to select the temperature sensor 95 measuring the temperature of the lower radiation thermometer 20, the upper radiation thermometer 25, and the wall surface of the chamber 161, the temperature sensor 93 measuring the temperature of the lower chamber window 64, the temperature sensor 92 measuring the temperature of the upper chamber window 63, or the temperature sensor 91 measuring the temperature of the susceptor 74. The reason is that the data measured by these sensors is considered to have a large correlation with the temperature data of the semiconductor wafer W.

The determination whether or not the data has the correlation with the temperature of the semiconductor wafer W is performed by the related information analyzing part 32a analyzing a relationship with the temperature data of the semiconductor wafer W. The related information analyzing part 32a determines presence or absence of correlation between the information acquired from each sensor and the temperature data of the semiconductor wafer W and a magnitude thereof. The information determined to have a large correlation with the temperature of the semiconductor wafer W in the related information analyzing part 32a is adopted as data necessary to create the learning model in the learning model creation part 32b. In the meanwhile, the data determined to have a small correlation with the temperature of the semiconductor wafer W may be excluded from the data used for creating the learning model in the leaning model creation part 32b.

### <Flow of Creating Learning Model in Calculation Part 32>

A flow of creating the learning model in the heat treatment apparatus 160 is described hereinafter.

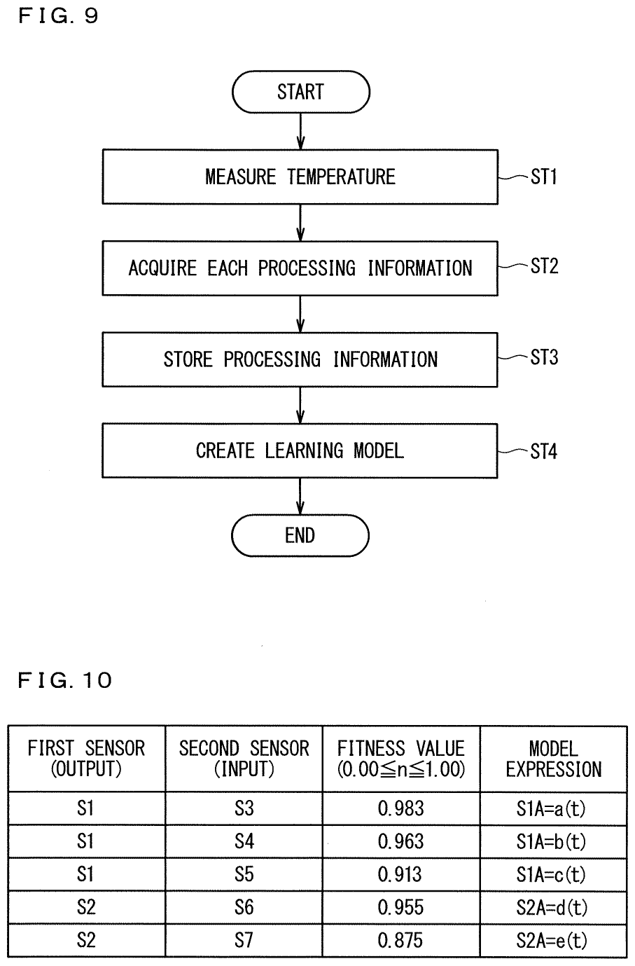

FIG. 9 is a flow chart illustrating a processing procedure of creating the learning model.

As illustrated in FIG. 9, a temperature, serving as teacher data, of a semiconductor wafer TC (a thermocouple-equipped semiconductor wafer TC hereinafter) to which a thermocouple is attached is measured by the thermocouple to create the learning model by the calculation part 32 (Step ST1). The temperature is measured in the plurality of thermocouple-equipped semiconductor wafers TC. Next, each data serving as the teacher data is acquired by each of the sensors S1 to S11 (processing information acquisition part 90) disposed in the heat treatment apparatus 160 at the same time of measuring the temperature of the thermocouple-equipped semiconductor wafer TC.

The temperature data and each data as the teacher data acquired in Step ST1 and Step ST2 are stored in the storage part 31 (Step ST3). Next, the learning model creation part 32b creates the learning model (Step ST4). The learning model is created by associating the temperature data with each data from the correlation of the temperature data with each data. For example, derived is a learning model expression of the temperature data of the thermocouple-equipped semiconductor wafer TC and luminance data of the lower radiation thermometer 20 (or the upper radiation thermometer 25) from a relationship between the temperature data by the thermocouple and the luminance data by the lower radiation thermometer 20 (or the upper radiation thermometer 25). The temperature of the semiconductor wafer W is derived from the luminance data by the lower radiation thermometer 20 (or the upper radiation thermometer 25) by this learning model expression.

In the similar manner, a learning model expression of the temperature data of the thermocouple-equipped semiconductor wafer TC and each data is derived from a relationship between the temperature data of the thermocouple-equipped semiconductor wafer TC and each data by the other sensor. The learning model expression of each data may be derived from these relationships.

In the learning model expression, weight is optimized in accordance with a magnitude of the correlation between data to be predicted and an actual measurement value acquired by each sensor. The weight increases as the correlation between the data to be predicted and the actual measurement value acquired by each sensor gets larger, and decreases as the correlation therebetween gets smaller.

FIG. 10 is a diagram illustrating a relationship between an output value predicted in the first sensor, an actual measurement value of the second sensor, and a fitness value.

In the present embodiment, a degree of accuracy between the output value predicted in the first sensor and the actual measurement value is calculated as the fitness value. This fitness value is acquired by optimizing the weight described above. That is to say, the fitness value indicates a magnitude of the correlation between the first sensor and the second sensor. In this manner, the output value predicted in one sensor can be derived from the actual measurement value of the other sensor from the relationship of the actual measurement value of two sensors. That is to say, the output value of one sensor can be predicted using the learning model expression which has been previously created.

As illustrated in FIG. 10, when the sensor S1 and the sensor S3 are adopted as the first sensor and the second sensor, respectively, the fitness value therebetween is 0.983, for example. In the similar manner, when the sensor S1 and the sensor S4 are adopted as the first sensor and the second sensor, respectively, the fitness value therebetween is 0.963, for example, when the sensor S1 and the sensor S5 are adopted as the first sensor and the second sensor, respectively, the fitness value therebetween is 0.913, for example, when the sensor S2 and the sensor S6 are adopted as the first sensor and the second sensor, respectively, the fitness value therebetween is 0.955, for example, and when the sensor S2 and the sensor S7 are adopted as the first sensor and the second sensor, respectively, the fitness value therebetween is 0.875, for example

Then, an output value S1A predicted in the first sensor S1 is calculated by a model expression S1A=a(t). The model expression a(t) is calculated by an expression of Math 1 described hereinafter, for example.

$$a ( t ) = n \times S 1 A ( t - 1 ) + n \times S 1 A ( t - 2 ) + n \times S 3 A ( t - 1 ) \qquad [ Math 1 ]$$

In the similar manner, the output value SIA predicted in the first sensor S1 is calculated by a model expression S1A=b(t), for example, the output value SIA predicted in the first sensor S1 is calculated by a model expression S1A=c(t), for example, the output value S2A predicted in the first sensor S2 is calculated by a model expression S2A=d(t), for example, and the output value S2A predicted in the first sensor S2 is calculated by a model expression S2A=e(t), for example, Each of b(t), c(t), d(t), and e(t) is the expression created as the learning model in the leaning model creation part 32b.

As shown by the expression of Math 1 described above, in the present embodiment, the learning model creation part 32b creates the learning model including a time-series element. Specifically, the learning model predicts the output value of the first sensor S1 based on one or more pieces of data in the time-series data measured by the first sensor S1 and one or more pieces of data in the time-series data measured by the second sensor S3. As shown by the expression of Math 1, the output value of the first sensor S1 at a point of time t (optional point of time) predicted by the learning model is calculated using the actual measurement value by the first sensor S1 at a point of past time t−1, the actual measurement value by the first sensor S1 at a point of past time t−2, and the second sensor S3 at a point of past time t−1, for example. The actual measurement value at the past time is used in this manner, thus the degree of accuracy of the output value measured by the first sensor S1 is improved. The degree of accuracy of the prediction of the output value of the first sensor is improved in this manner, the temperature of the semiconductor wafer W in the chamber 161 can also be measured with high accuracy before reaching the stable temperature.

Herein, when the learning model expression such as the expression of Math 1 is created, it is necessary to determine how much past data to include in the prediction for each of the actual measurement value by the first sensor S1 and the actual measurement value by the second sensor S3. This determination may be appropriately set as a hyper parameter. For example, in a case of a component having a high thermal conductivity, the predicted output value may be calculated by the learning model expression of only immediately preceding data (for example, data at a point of past time t−1). In the meanwhile, in a case of a component having a low thermal conductivity, the predicted output value is preferably calculated by the learning model expressing also including data of previous data in several steps (for example, data at points of times t−1, t−2, t−3, . . . ). In this manner, the hyper parameter is set in consideration of quality of a component measured by each sensor and the fitness value of the output value of the sensor having correlation.

The degree of accuracy of the output value measured in the first sensor S1 calculated in this manner is improved, thus the learning model can be also be used for feedback control with high accuracy and prediction of a recipe in the manufacturing process of the semiconductor wafer W using this output value.

### <Flow of Processing of Semiconductor Wafer W Using Learning Model>

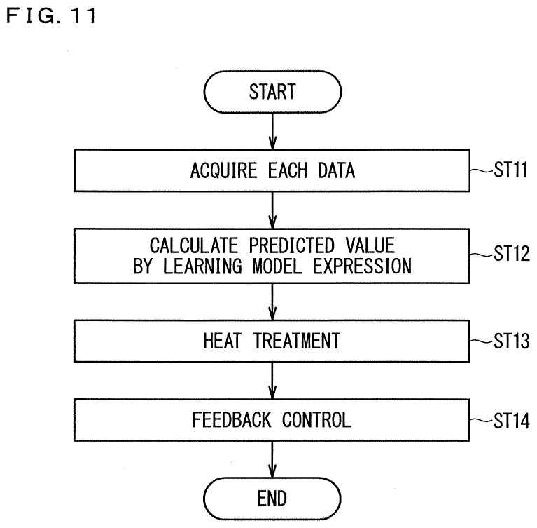

FIG. 11 is a flow chart illustrating a processing procedure of the semiconductor wafer W using the learning model.

As illustrated in FIG. 11, each data is firstly acquired by each of the sensors S1 to S11 including the lower radiation thermometer 20 to measure the accurate temperature of the semiconductor wafer W by the learning model (Step ST11).

Next, the temperature of the semiconductor wafer W at the point of time t is predicted (Step ST12). The learning model expression is used, thus the prediction part 32c predicts the temperature of the semiconductor wafer W at the point of time t from each data. At this time, as described above, the relationship with the past actual measurement value of the sensor necessary for the learning model expression is also included, thus the temperature of the semiconductor wafer W is predicted with high accuracy. The temperature of the semiconductor wafer W is appropriately predicted until the heat treatment of the semiconductor wafer W is finished.

In such a state, the heat treatment is performed on the semiconductor wafer W in the chamber 161 (Step ST13). During the heat treatment, the feedback control is performed using the temperature predicted in Step ST 12 (Step ST14). In this feedback control, for example, the output value predicted for the temperature of the semiconductor wafer W and a target value set in the recipe are compared, and when there is a difference between the predicted output value and the target value (or when a difference exceeds a preset threshold value), control having various configurations is performed in the heat treatment apparatus 160 so that the predicted output value and the target value coincide with each other. The control having various configuration indicates an output value of the halogen lamps HL or the flash lamps HL, a heating time of the halogen lamps HL, or a supply amount of supply gas, for example. Accordingly, the predicted output value can get closer to the target value.

In the manner described above, the heat treatment of the semiconductor wafer W in the present embodiment is finished.

### <Effect Generated by Embodiments Described Above>

Described next is an example of an effect generated by the embodiments described above. In the description hereinafter, the effect is described based on a specific example exemplified in the embodiments described above, however, the specific example may be replaced with the other specific configuration exemplified in the specification of the present application.

The configuration may be replaced over the plurality of embodiments. That is to say, also applicable is a case where configurations exemplified in different embodiments are combined to have the similar effect.

The heat treatment apparatus 160 according to the embodiments described above includes the chamber 161 housing the semiconductor wafer W, the halogen heating part 4 and the flash heating part 5 heating the semiconductor wafer W, the plurality of sensors S1 to S11 measuring the parameter relating to the heating of the semiconductor wafer W, the storage part 31 housing the data measured by the plurality of sensors S1 to S11, and the calculation part 32 predicting the output value of the first sensor based on the data measured by the first sensor and the data measured by the second sensor having correlation with the first sensor in the plurality of sensors S1 to S11.

According to such a configuration, the temperature of the semiconductor wafer W is managed with high accuracy even before the chamber 161 reaches the stable temperature. That is to say, the temperature of the semiconductor wafer W can be predicted with high accuracy, thus there is no need to wait for the inner side of the chamber 161 reaching the stable temperature using a dummy wafer. Accordingly, cost and a time necessary to process the dummy wafer can be omitted, and reduction of the productivity can be suppressed. The temperature of the semiconductor wafer W in the chamber 161 can also be measured with high accuracy before reaching the stable temperature.

The calculation part 32 predicts the output value of the first sensor based on one or more pieces of time-series data measured by the first sensor and one or more pieces of time-series data measured by the second sensor.

According to such a configuration, the output value of the sensor measuring the other configuration part can be predicted with high accuracy from the data even when the data is acquired by measuring a configuration part considered to have relatively a small correlation.

The calculation part 32 calculates a degree of accuracy between the output value which is predicted and the data which is actually measured in the first sensor as the fitness value indicating the magnitude of correlation between the first sensor and the second sensor.

According to such a configuration, even when there is a small correlation between the output value of the first sensor and the output value of the second sensor, the output value of the first sensor is predicted with high accuracy by adjusting the fitness value.

The plurality of sensors S1 to S11 include the temperature sensor (the lower radiation thermometer 20 or the upper radiation thermometer 25) measuring the temperature of the semiconductor wafer W.

According to such a configuration, the temperature of the semiconductor wafer W is managed with high accuracy in the heat treatment which is important for improving quality of the semiconductor wafer W.

The plurality of sensors S1 to S11 include the temperature sensor 95 measuring the temperature of the wall surface of the chamber 161.

According to such a configuration, the output value of the temperature sensor (the lower radiation thermometer 20 or the upper radiation thermometer 25) of the semiconductor wafer W can be predicted with high accuracy using the temperature data of the wall surface of the chamber 161 considered to have the large correlation with the temperature of the semiconductor wafer W.

The heat treatment apparatus 160 further includes the halogen heating part 4 irradiating the semiconductor wafer W housed in the chamber 161 with light to preheat the semiconductor wafer W and the flash heating part 5 irradiating the semiconductor wafer W with light to make the semiconductor wafer W reach the treatment temperature. Then, provided to the chamber 161 are the upper chamber window 63 and the lower chamber window 64 as the light transmissive windows transmitting the light emitted from the halogen heating part 4 and the flash heating part 5. Furthermore, the plurality of sensors S1 to S11 include the temperature sensor S92 or the temperature sensor S93 measuring the temperature of the upper chamber window 63 or the lower chamber window 64.

According to such a configuration, the output value of the temperature sensor (the lower radiation thermometer 20 or the upper radiation thermometer 25) of the semiconductor wafer W can be predicted with high accuracy using the temperature data of the upper chamber window 63 or the lower chamber window 64 considered to have the large correlation with the temperature of the semiconductor wafer W.

The heat treatment apparatus 160 further includes the susceptor 74 placing the semiconductor wafer W and transmitting the light emitted from the halogen heating part 4 or the flash heating part 5 to the semiconductor wafer W. The plurality of sensors S1 to S11 include the temperature sensor 91 measuring the temperature of the susceptor 74.

According to such a configuration, the output value of the temperature sensor (the lower radiation thermometer 20 or the upper radiation thermometer 25) of the semiconductor wafer W can be predicted with high accuracy using the temperature data of the susceptor 74 considered to have the large correlation with the temperature of the semiconductor wafer W.

### <Modification Example in Embodiments Described Above>

In the embodiments described above, material properties, materials, dimensions, shapes, relative arrangement relations, conditions for implementation, and so forth for the respective constituent elements may be described, however, these represent a mare example in all aspects, and are not limited to the description in the specification of the present application.

Accordingly, it is understood that numerous other modifications variations, and equivalents can be devised without departing from the scope of the technique disclosed in the specification of the present application. For example, the following cases where at least one of the constituent elements is to be modified, added, or omitted, further, at least one of the constituent elements of at least one of the embodiments is extracted and then combined with constituent elements of the other embodiment, are involved.

In the embodiments described above, the calculation part 32 includes the related information analyzing part 32a and the learning model creation part 32b, however, the configuration is not limited thereto. It is also applicable that the calculation part 32 does not include the related information analyzing part 32a, however, the storage part 31 stores the correlation with the temperature of the semiconductor wafer W which has been previously analyzed (or set) instead. It is also applicable that the calculation part 32 (232) does not include the learning model creation part 32b, however, the storage part 31 stores the learning model which has been previously created instead. Then, also applicable is a configuration that the calculation part 32 calculates the output value predicted for the temperature of the semiconductor wafer W based on this stored learning model.

In the embodiments described above, the calculation part 32 includes the prediction part 32c, however, the configuration is not limited thereto. Also applicable is a configuration that the calculation part 32 does not include the prediction part 32c but a cloud which can remotely have access to the heat treatment apparatus 160 (260) includes the function of the prediction part 32c. Also applicable in this case is a configuration that the data acquired by the processing information acquisition part 90 (each sensor) and the measurement value by the lower radiation thermometer 20 (and/or the upper radiation thermometer 25) is transmitted to the cloud, and the controller 3 receives a result predicted in the cloud. Also applicable in this case is a configuration that the cloud stores the data acquired by the processing information acquisition part 90 (each sensor) and the measurement value by the lower radiation thermometer 20 (and/or the upper radiation thermometer 25). Also applicable is a configuration that the cloud includes the whole function of the controller 3. Further applicable is a configuration including the function of the prediction part 32c which can have access to (transmit and receive the data to and from) the controller 3 by wire or wirelessly regardless of the cloud.

Adopted in the embodiments described above is the configuration that the output value of the first sensor is predicted based on the data measured by the first sensor and the data measured by the second sensor in the plurality of sensors S1 to S11, however, the configuration is not limited thereto.

The output value of the first sensor may be predicted based on the data measured by the first sensor, the data measured by the second sensor, and further the data measured by the third sensor. The output value of the first sensor may be predicted based on the data measured by a large number of sensors such as the fourth sensor and the fifth sensor.

Further, in the embodiments described above, when names of materials are stated unless otherwise specified, an alloy of the material and other additives, and so forth are included, so far as consistent with the embodiments.

### EXPLANATION OF REFERENCE SIGNS

3 controller
4 halogen heating part
5 flash heating part
7 holder
10 transfer mechanism
11 transfer arms
12 lift pins
13 horizontal movement mechanism
14 elevating mechanism
15 input part
16 display part
20 lower radiation thermometer
21, 26 transparent window
24, 29 infrared radiation sensor
25 upper radiation thermometer
31 storage part
32 calculation part
32a related information analyzing part
32b learning model creation part
32c prediction part
41 chassis
43, 52 reflector
49 power supply part
49a ammeter
51 chassis
53 lamp light radiation window
61 chamber side portion
61a, 61b through hole
62 recessed portion
63 upper chamber window
64 lower chamber window
65 heat treatment space
66 transport opening
68, 69 reflective ring
71 base ring
72 coupling portions
74 susceptor
75 holding plate
75a holding surface
76 guide ring
77 support pin
78 opening
79 through hole
81 gas supply opening
82, 87 buffer space
83 gas supply pipe
84 valve
85 treatment gas supply source
86 gas exhaust opening
88 gas exhaust pipe
89, 192 valve
90 related information acquisition part
91, 92, 93, 94, 95 temperature sensor
96, 97 light volume sensor
98 flowmeter
160 heat treatment apparatus
161 chamber
162 gate valve
190 exhaust mechanism
191 gas exhaust pipe
TC thermocouple-equipped semiconductor wafer
W semiconductor wafer

1. A heat treatment apparatus, comprising:
a chamber housing a substrate;
a heating part heating the substrate;
a plurality of sensors measuring a parameter relating to the heating of the substrate;
a storage part storing data measured by the plurality of sensors; and
a calculation part predicting an output value of the first sensor based on data measured by a first sensor and data measured by a second sensor having a correlation with the first sensor in the plurality of sensors.

2. The heat treatment apparatus according to claim 1, wherein
the calculation part predicts an output value of the first sensor based on one or more pieces of time-series data measured by the first sensor and one or more pieces of time-series data measured by the second sensor using a leaning model which has been previously created.

3. The heat treatment apparatus according to claim 1, wherein
the calculation part calculates a degree of accuracy between the output value which is predicted and data which is actually measured as a fitness value indicating a magnitude of correlation between the first sensor and the second sensor.

4. The heat treatment apparatus according to claim 1, wherein
the plurality of sensors include a temperature sensor measuring a temperature of the substrate.

5. The heat treatment apparatus according to claim 1, wherein
the plurality of sensors include a temperature sensor measuring a temperature of a wall surface of the chamber.

6. The heat treatment apparatus according to claim 1, further comprising
a preheating part irradiating the substrate housed in the chamber with light to preheat the substrate; and a main heating part irradiating the substrate with light to make the substrate reach a treatment temperature, wherein
a light transmissive window transmitting light emitted from the preheating part and the main heating part is provided to the chamber, and
the plurality of sensors include a temperature sensor measuring a temperature of the light transmissive window.

7. The heat treatment apparatus according to claim 6, further comprising
a susceptor locating the substrate and transmitting light emitted from the preheating part or the main heating part to the substrate, wherein
the plurality of sensors include a temperature sensor measuring a temperature of the susceptor.
